(19) United States
(12) Patent Application Publication
(10) Pub. No.: US 2026/0287616 A9
(43) Pub. Date: Sep. 24, 2026

(54) VIBRATION ISOLATION LAYERS, MEASUREMENT SYSTEMS THAT INCLUDE THE VIBRATION ISOLATION LAYERS, AND RELATED METHODS

(71) Applicant: FormFactor, Inc., Livermore, CA (US)

(72) Inventors: Michael E. Simmons, Colton, OR (US); Divya Pratap, Beaverton, OR (US)

(21) Appl. No.: 19/097,133

(22) Filed: Apr. 1, 2025

Related U.S. Application Data
(60) Provisional application No. 63/659,267, filed on Jun. 12, 2024.
(60) Provisional application No. 63/718,999, filed on Nov. 11, 2024.

(51) Int. Cl. G01R 1/07; F16F 15/00; F16F 15/027; G01N 21/95; H10P 72/30; H10P 72/50; H10P 74/20

(52) U.S. Cl. CPC G01R 1/071; F16F 15/002; F16F 15/027; G01N 21/9501; H10P 72/3218; H10P 72/50; H10P 74/203; H10P 74/207

(57) ABSTRACT

Vibration isolation layers, measurement systems that include the vibration isolation layers, and related methods are disclosed herein. The vibration isolation layers include a platform and a plurality of vibration isolation mechanisms positioned to support the platform relative to a mounting region that supports the vibration isolation layer. The platform may define an upper surface configured to support a supported assembly that includes at least one of a probe station and a loader. The platform may define a recess sized to receive at least a region of the probe station and/or the loader. The recess may extend into the platform. The plurality of vibration isolation mechanisms may be positioned to support the platform relative to a mounting region that supports the vibration isolation layer and/or may be configured to permit relative motion between the platform and the mounting region to vibrationally isolate the platform from the mounting region.

### RELATED APPLICATIONS

This application claims priority to U.S. Provisional Patent Application No. 63/659,267, which was filed on Jun. 12, 2024, and to U.S. Provisional Patent Application No. 63/718,999, which was filed on Nov. 11, 2024, and the complete disclosures of which are hereby incorporated by reference.

### FIELD OF THE DISCLOSURE

The present disclosure relates generally to vibration isolation layers, to measurement systems that include the vibration isolation layers, and to related methods.

### BACKGROUND OF THE DISCLOSURE

Conventional probe stations may be utilized to test devices under test (DUTs) in the form of optical and/or optoelectronic devices. Such conventional probe stations typically include one or more optical probes. Consistent, repeatable, and/or continuous alignment between the one or more optical probes and the DUT may be important, and variations in alignment may cause variations in test results. Vibrations that originate external the conventional probe station and are present within a test environment within which the conventional probe station is installed may cause misalignment and/or relative motion between the one or more optical probes and the DUT, thereby degrading test quality. Thus, there exists a need for measurement systems that include a vibration isolation layer.

### SUMMARY OF THE DISCLOSURE

Vibration isolation layers, measurement systems that include the vibration isolation layers, and related methods are disclosed herein. The vibration isolation layers include a platform and a plurality of vibration isolation mechanisms positioned to support the platform relative to a mounting region that supports the vibration isolation layer. The platform may define an upper surface configured to support a supported assembly that includes at least one of a probe station and a loader. The platform may define a recess sized to receive at least a region of the probe station and/or the loader. The recess may extend into the platform. The plurality of vibration isolation mechanisms may be positioned to support the platform relative to a mounting region that supports the vibration isolation layer and/or may be configured to permit relative motion between the platform and the mounting region to vibrationally isolate the platform from the mounting region.

The measurement systems include a vibration isolation layer and a supported assembly. The supported assembly may be supported by the upper surface of the platform. The supported assembly may include a measurement layer configured to test a device under test (DUT) formed on a substrate and/or an optical measurement layer configured to optically test the DUT. The optical measurement layer may include an optical measurement layer controller programmed to control the operation of the optical measurement layer and/or of the vibration isolation layer.

The methods include methods of installing a measurement system configured to test a device under test (DUT) that is formed on a substrate and include positioning a vibration isolation layer, positioning a supported assembly, vibrationally isolating the supported assembly, and controlling the operation of the vibration isolation layer. The positioning the vibration isolation layer may include positioning within a mounting region. The positioning the supported assembly may include positioning the supported assembly on an upper surface of a platform of the vibration isolation layer. The supported assembly may include a probe station and/or an optical measurement layer configured for optical communication with the DUT. The optical measurement layer may include an optical measurement layer controller. The vibrationally isolating may include vibrationally isolating the supported assembly from the mounting region via the vibration isolation layer. The controlling may include controlling the operation of the vibration isolation layer utilizing the optical measurement layer controller.

### BRIEF DESCRIPTION OF THE DRAWINGS

FIG. 1 is a schematic illustration of examples of a measurement system according to the present disclosure.

FIG. 2 is a plot illustrating an example of vibration within a test environment of a measurement system, according to the present disclosure.

FIG. 3 is a plot illustrating examples of vibration damping that may be achieved utilizing vibration isolation mechanisms of vibration isolation layers of measurement systems, according to the present disclosure.

FIG. 4 is a flowchart depicting examples of methods of installing a measurement system, according to the present disclosure, which is configured to test a device under test (DUT) that is formed on a substrate.

### DETAILED DESCRIPTION AND BEST MODE OF THE DISCLOSURE

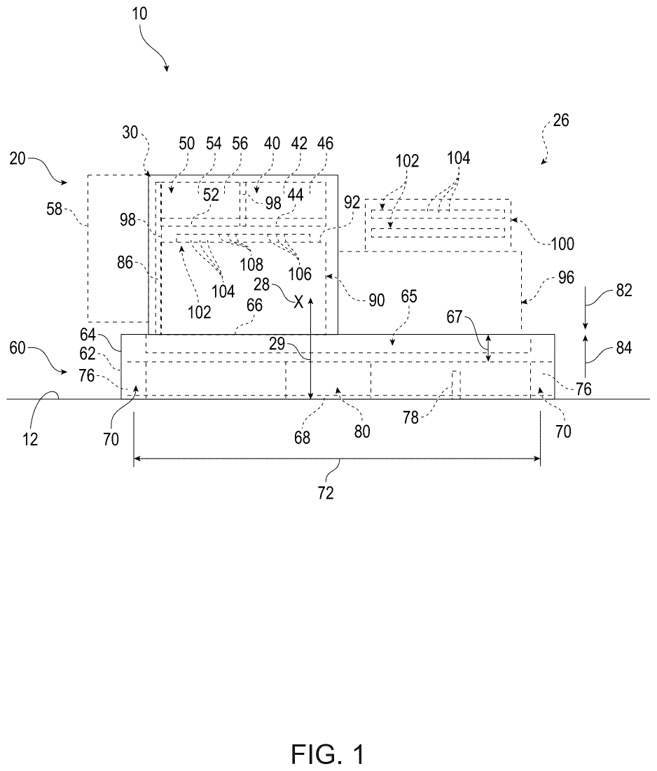

FIGS. 1-4 provide examples of measurement systems 20, of environmental vibration experienced by measurement systems 20, of vibration damping that may be achieved utilizing measurement systems 20, and of methods 200 for installing measurement systems 20, according to the present disclosure. Elements that serve a similar, or at least substantially similar, purpose are labeled with like numbers in each of FIGS. 1-4, and these elements may not be discussed in detail herein with reference to each of FIGS. 1-4. Similarly, all elements may not be labeled in each of FIGS. 1-4, but reference numerals associated therewith may be utilized herein for consistency. Elements, components, and/or features that are discussed herein with reference to one or more of FIGS. 1-4 may be included in and/or utilized with any of FIGS. 1-4 without departing from the scope of the present disclosure.

In general, elements that are likely to be included in a particular embodiment are illustrated in solid lines, while elements that may be optional are illustrated in dashed lines. However, elements that are shown in solid lines may not be essential to all embodiments and, in some embodiments, may be omitted without departing from the scope of the present disclosure.

FIG. 1 is a schematic illustration of examples of a measurement system 20 according to the present disclosure. Measurement systems 20 may be positioned and/or mounted within a test environment 10, such as a fab, a wafer fab, a laboratory, and/or a clean room. In specific examples, measurement systems 20 may be supported by, supported on, positioned on, and/or operatively attached to a mounting region 12, such as a floor, of the test environment.

Measurement systems 20 include a vibration isolation layer 60 that includes a platform 64 and a vibration isolation mechanism 70, or a plurality of vibration isolation mechanisms 70, examples of which are disclosed herein. Measurement systems 20 also include a supported assembly 26 that is supported by the vibration isolation mechanism, such as via the platform. Supported assembly 26 includes a probe station 30, a measurement layer 40, a loader 96, and/or a translation assembly 98.

Probe station 30 includes a support surface 92, which is configured to support a substrate 102. This may include support of the substrate relative to and/or with respect to the measurement layer. Probe station 30 may include any suitable structure that may be adapted, configured, designed, and/or constructed to support substrate 102 and/or to define support surface 92. As an example, probe station 30 may include a chuck 90 that defines the support surface. Examples of the chuck include a thermal chuck, a temperature-controlled chuck, a vacuum chuck, and/or an electrically shielded chuck.

Measurement layer 40 is configured to test a device under test (DUT) 104, examples of which include an electronic device, an optical device, and/or an optoelectronic device. DUT 104 may be formed on substrate 102, examples of which include a wafer, a semiconductor wafer, a silicon wafer, and/or a Group III-V semiconductor wafer.

Measurement layer 40 may be configured to test DUT 104 in any suitable manner. As an example, measurement layer 40 may include an electrical measurement layer 42, which may be configured to electrically test DUT 104. Electrical measurement layer 42 may include a plurality of electrical probes 44, which may be configured to contact, to electrically contact, or to physically and electrically contact, corresponding contact pads 106 of DUT 104 to electrically test the DUT.

When measurement layer 40 includes electrical measurement layer 42, probe station 30 and/or electrical measurement layer 42 thereof may include an electrical signal generation and analysis assembly 46. The electrical signal generation and analysis assembly may be configured to provide an electric test signal to the DUT via the plurality of electrical probes 44 and/or to receive an electric resultant signal from the DUT via the plurality of electrical probes. Examples of the electrical signal generation and analysis assembly include an electric current source, an electric voltage source, a function generator, a voltage meter, a current meter, and/or an impedance analyzer.

As discussed in more detail herein, various components of measurement system 20 may be manufactured and/or provided by different manufacturers and/or vendors. With this in mind, and in some examples, electrical measurement layer 42 may form a portion of probe station 30, may be integral with probe station 30, may be manufactured by the same manufacturer as probe station 30, and/or may provided by the same vendor as probe station 30.

As another example, measurement layer 40 may include an optical measurement layer 50, which may be configured to optically test DUT 104. Optical measurement layer 50 may include a plurality of optical probes 52, which may be configured for optical communication, or non-contact optical communication, with the DUT, such as with one or more optical devices 108 of the DUT. When measurement layer 40 includes optical measurement layer 50, probe station 30 and/or optical measurement layer 50 thereof may include an optical signal generation and analysis assembly 54. The optical signal generation and analysis assembly may be configured to provide an optical test signal to the DUT via the plurality of optical probes 52 and/or to receive an optical resultant signal from the DUT via the plurality of optical probes. Examples of the optical signal generation and analysis assembly include an electromagnetic radiation source, a light source, a laser, and/or an electromagnetic radiation detector.

In some examples, optical measurement layer 50 may include an optical microscope 56. The optical microscope may be configured to collect an optical image of at least one of the plurality of optical probes 52 and/or of at least a region of DUT 104, such as of optical device 108 of the DUT. Such a configuration may permit and/or facilitate optical alignment between the plurality of optical probes and the DUT.

When measurement system 20 includes optical measurement layer 50, vibration isolation layer 60 may be configured to vibrationally isolate platform 64 from mounting region 12 to provide an amount of vibration isolation that is based, at least in part, on a target maximum magnitude of vibrational motion between the plurality of optical probes 52 and DUT 104 and/or optical devices 108 thereof. Stated differently, optical measurement layer 50 and/or alignment between optical probes 52 and DUT 104 may be sensitive, or may be relatively more sensitive, compared to electrical measurement layer 42 and/or compared to alignment between electrical probes 44 and the DUT. With this in mind, vibration isolation layer 60 specifically and/or purposefully may be configured to provide vibration isolation that is sufficient to permit consistent, reliable, precise, and/or accurate operation of optical measurement layer 50 within measurement system 20.

This may be accomplished in any suitable manner. As an example, and as discussed, various components of measurement system 20 may be manufactured and/or provided by different manufacturers and/or vendors. In some such examples, optical measurement layer 50 may include and/or be a modular optical measurement layer that may be manufactured by a first manufacturer. The first manufacturer may be a different manufacturer from a second manufacturer of one or more other components of measurement system 20, such as probe station 30 and/or of electrical measurement layer 42. Additionally or alternatively, optical measurement layer 50 may be provided by a first vendor, which may be a different vendor from a second vendor of one or more other components of measurement system 20, such as probe station 30 and/or electrical measurement layer 42. Additionally or alternatively, optical measurement layer 50 may be operatively attached to probe station 30 and/or may be configured to be repeatedly attached to, and separated from, the probe station. In some such examples, vibration isolation layer 60 may be provided by the same manufacturer and/or vendor as optical measurement layer 50, such as the first vendor. As such, properties and/or characteristics of vibration isolation layer 60 may be specifically configured in view of desired vibration isolation for the optical measurement layer. Stated differently, vibration isolation layer 60 may be configured to facilitate efficient and/or effective operation of optical measurement layer 50, such as via providing a target, desired, and/or needed level of vibration isolation for measurement system 20 that is based upon optical measurement layer 50, optical devices 108, and/or a maximum amount of relative motion between the optical measurement layer and the optical devices that provides a desired measurement resolution and/or signal-to-noise ratio for optical measurements performed utilizing the optical measurement layer.

In some examples, optical measurement layer 50 may include an optical measurement layer controller 58. The optical measurement layer controller may be programmed to control the operation of the optical measurement layer, such as of optical probes 52, optical signal generation and analysis assembly 54, and/or optical microscope 56. As discussed in more detail herein, optical measurement layer controller 58 also may be configured to control the operation of vibration isolation layer 60 and/or of one or more components thereof, such as to provide the desired vibration isolation for the optical measurement layer.

Loader 96 is configured to receive a cassette 100, which includes a plurality of substrates 102. Each substrate 102 includes a corresponding plurality of DUTs 104. Loader 96 also may be configured to move a selected substrate of the plurality of substrates between the cassette and the probe station, such as to facilitate testing of one or more DUTs formed on the selected substrate by the probe station. In a specific example, the loader may be configured to remove the selected substrate from the cassette and to position the selected substrate on support surface 92 of the probe station. Additionally or alternatively, the loader may be configured to remove the selected substrate from the support surface of the probe station and to position the selected substrate within the cassette. Examples of loader 96 include a docking station for cassette 100, a robotic arm, and/or a transfer robot.

Translation assembly 98 is configured to move support surface 92 and measurement layer 40 relative to one another, such as to permit and/or facilitate alignment between the measurement layer and DUT 104. This may include moving the support surface relative to the measurement layer and/or moving the measurement layer relative to the support surface. In some examples, translation assembly 98 additionally or alternatively may be configured to move electrical measurement layer 42 and optical measurement layer 50 relative to one another and/or to permit, facilitate, and/or provide independent motion of the electrical measurement layer and the optical measurement layer. Such a configuration may permit and/or facilitate independent alignment between electrical probes 44 and the DUT and also between optical probes 52 and the DUT. Examples of translation assembly 98 include an actuator, a linear actuator, a rotary actuator, a manual actuator, and/or a motorized actuator.

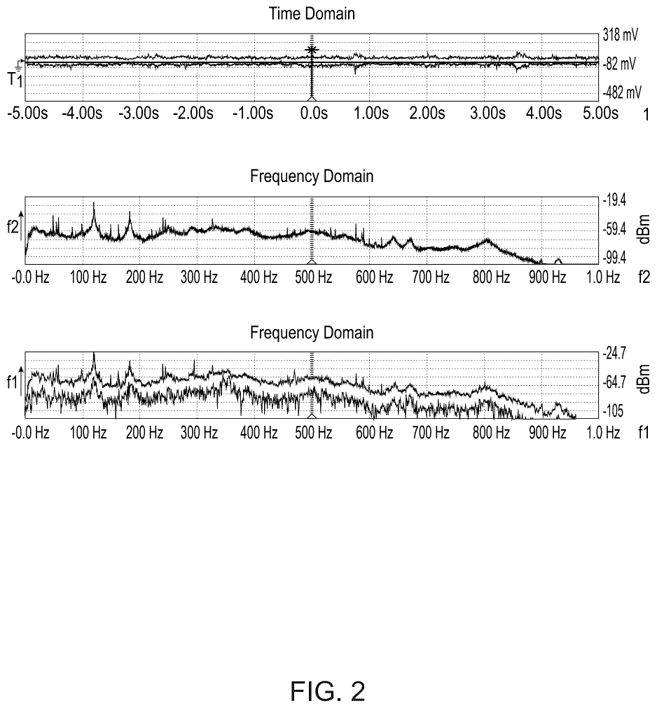

As discussed, and as illustrated in FIG. 2, vibrations may be present within test environment 10. As also illustrated in FIG. 2, these vibrations may have and/or exhibit characteristic frequencies, such as may be based upon, responsive to, and/or a result of construction aspects of test environment 10 and/or hardware, equipment, and/or machines that are within, proximate, and/or in mechanical communication with test environment 10. Such vibrations may be detrimental to tests that are performed on DUT 104 by measurement systems 20.

As an example, such vibrations may cause relative motion and/or at least partial misalignment between optical probes 52 and optical devices 108 of DUT 104 and/or between electrical probes 44 and contact pads 106 of the DUT. In some examples, this misalignment may be sufficient to make it difficult, or even impossible, for measurement systems 20 to test DUTs 104 and/or for the measurement systems to test the DUTs at a desired accuracy, at a desired precision, and/or with a desired signal-to-noise ratio. In some examples, this misalignment may introduce additional noise into tests performed on DUTs 104 by measurement systems 20. It may be desirable to decrease, to minimize, and/or to eliminate relative motion and/or vibration within measurement systems 20, between various components of measurement systems 20, and/or between one or more components of measurement layer 40 and support surface 92 and/or DUT 104 that is supported by the support surface.

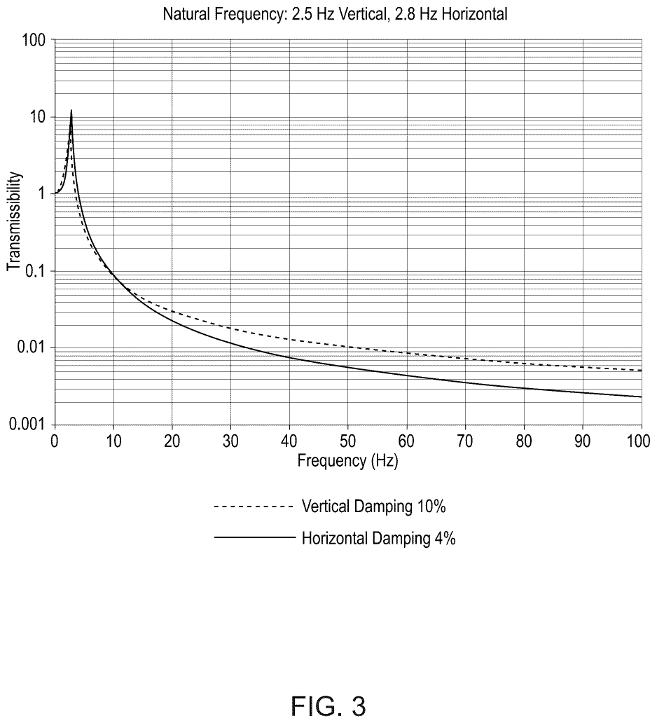

With the above in mind, vibration isolation layer 60 may be configured to decrease transfer and/or conveyance of vibrations from test environment 10 to and/or into supported assembly 26 of measurement systems 20. Stated differently, vibration isolation layers 60 may be configured to decrease, to minimize, and/or to eliminate relative motion and/or vibration, which originates within test environment 10 and external to measurement systems 20, within measurement systems 20, between various components of measurement systems 20, within supported assembly 26, between one or more components of measurement layer 40 and support surface 92, and/or between one or more components of optical measurement layer 50 and DUT 104 that is supported by the support surface. Vibration isolation layer 60 also may be referred to herein as and/or may be a vibration isolation pallet, a vibration isolation assembly, and/or a vibration isolation structure. FIG. 3 is a plot illustrating examples of vibration damping that may be achieved utilizing vibration isolation mechanisms 70 of vibration isolation layers 60 of measurement systems 20, according to the present disclosure.

This vibration damping may be accomplished in any suitable manner. As an example, and as discussed, vibration isolation layer 60 includes platform 64 that defines upper surface 66. Supported assembly 26 may be supported by platform 64, may be supported by upper surface 66, may be positioned on platform 64, may be positioned on upper surface 66, may be operatively attached to platform 64, and/or may be operatively attached to upper surface 66. Platform 64 may be relatively large and/or massive, thereby decreasing the potential for vibration thereof. As examples, platform 64 may define a platform thickness 67 of at least 100 millimeters (mm), at least 120 mm, at least 140 mm, at least 160 mm, at least 180 mm, at least 200 mm, at most 400 mm, at most 350 mm, at most 300 mm, at most 250 mm, at most 200 mm, and/or at most 150 mm thick.

As additional examples, platform 64 may be formed and/or defined from a dense material, examples of which include a metal, a steel, a stainless steel, lead, a stone, a mineral glass, and/or granite. As additional examples, platform 64 may be formed and/or defined by a platform material with a density of at least 2 grams per cubic centimeter (g/cc), at least 2.5 g/cc, at least 3 g/cc, at least 4 g/cc, at least 5 g/cc, at least 6 g/cc, at least 7 g/cc, at least 8 g/cc, at least 9 g/cc, at least 10 g/cc, at least 11 g/cc, at least 12 g/cc, at most 16 g/cc, at most 14 g/cc, at most 12 g/cc, at most 10 g/cc, at most 8 g/cc, at most 6 g/cc, and/or at most 4 g/cc.

As additional examples, platform 64 may be formed and/or defined from a platform material that does not propagate, or that dampens, vibration. Examples of the platform material include a non-ringing material, a self-damping material, and/or a vibration-damping material.

Vibration isolation layer 60 also includes at least one vibration isolation mechanism 70. Examples of vibration isolation mechanism 70 include a passive vibration isolator, a passive air vibration isolator, a passive elastomeric gas-containing volume that is configured to be inflated to vibrationally isolate the platform from the mounting region, and/or a passive air vibration isolation spring. Additional examples of vibration isolation mechanism 70 include an actively controlled vibration isolator, an actively controlled air vibration isolator, an active air vibration isolation spring, and/or an actively controlled elastomeric gas-containing volume configured to be selectively inflated to vibrationally isolate the platform from the mounting region.

In some examples, vibration isolation layer 60 may include a gas pressure regulation structure 76, which may be configured to regulate an internal gas pressure within vibration isolation mechanisms 70. When vibration isolation mechanisms 70 include passive and/or active air vibration isolation springs, the vibration isolation layer 60 also may be referred to herein as and/or may be an air spring vibration isolation layer 62. Examples of gas pressure regulation structure 76 include a pressure regulator, a passive pressure regulator, an actively controlled pressure regulator, a valve, a diaphragm, and/or a pressure sensor.

As used herein, the term “passive,” when utilized to describe a component, such as of measurement systems 20 and/or of vibration isolation layers 60, refers to a component that performs a specified function without control and/or regulation. Stated differently, the term “passive” refers to a component that performs a specified function based upon, or based solely upon, one or more inherent properties of the component. As an example, a passive elastomeric gas-containing volume may passively provide vibration isolation by permitting relative motion between two components that are interconnected via the passive elastomeric gas-containing volume.

Conversely, and as used herein, the terms “active” and/or “actively,” when utilized to describe a control strategy, a regulation strategy, and/or a component, such as of measurement systems 20 and/or of vibration isolation layers 60, refers to a component that performs the specified function utilizing one or more sensors, controllers, and/or actuators. Stated differently, the terms “active” and/or “actively” refer to a component that performs the specified function based, at least in part, upon one or more detections by corresponding sensors, one or more actions by corresponding actuators, and/or one or more directions by corresponding controllers. As an example, a gas pressure within an actively controlled elastomeric gas-containing volume may be controlled and/or regulated to provide vibration isolation and/or to increase, or improve, vibration isolation when compared to a passive elastomeric gas-containing volume.

Vibration isolation mechanisms 70 may support platform 64 relative to mounting region 12, thereby permitting relative motion between the platform and the mounting region. As such, vibration isolation mechanisms 70 may decrease a potential for transfer of vibration from test environment 10, via mounting region 12, and to and/or into probe station 30.

In some examples, and as discussed, vibration isolation mechanisms 70 may be passive. In other examples, and as also discussed, the vibration isolation mechanisms may be active, may be actively controlled, and/or may be actively regulated. In a specific example, optical measurement layer controller 58 may at least partially control the operation of vibration isolation mechanisms 70. In a more specific example, optical measurement layer controller 58 may be programmed to control and/or regulate a height of platform 64 via control and/or regulation of a height of vibration isolation mechanisms 70. Such a configuration may permit and/or facilitate improved loading of cassette 100 on loader 96 and subsequent testing of DUT 104 by probe station 30.

As an example, optical measurement layer controller 58 may lower platform 64 to a lower height limit and/or against a lower height stop 78 when cassette 100 is positioned on loader 96 and/or removed from loader 96. This may include moving the platform, or upper surface 66 of the platform, in a downward direction, such as is indicated at 82 in FIG. 1. Such a configuration may define a fixed and/or predetermined height for platform 64 and/or for upper surface 66 and/or may decrease a potential for misalignment between the cassette and a device that is utilized to position the cassette relative to the loader.

As another example, and subsequent to the cassette being positioned on the loader, optical measurement layer controller 58 may raise platform 64 to a vibration isolation height. This may include moving the platform, or upper surface 66, in an upward direction, such as is indicated at 84 in FIG. 1. The vibration isolation height may be a height at which the platform effectively, or most effectively, isolates probe station 30 from vibration within test environment 10.

As yet another example, optical measurement layer controller 58 may be programmed to detect vibration within vibration isolation layer 60, within platform 64, between platform 64 and mounting region 12, between optical probes 52 and optical devices 108, and/or within optical measurement layer 50. In such a configuration, the optical measurement controller additionally or alternatively may be programmed to control the operation of vibration isolation layer 60 based, at least in part, on the detected vibration. The vibration may be detected in any suitable manner. As an example, a vibration detector 86 may be utilized to detect the vibration. As another example, the vibration may be detected as variation and/or noise in optical signals conveyed between optical probes 52 and optical devices 108. Examples of vibration detector 86, when utilized, include an accelerometer, a velocity sensor, a displacement sensor, and/or a piezoelectric sensor.

As illustrated in dashed lines in FIG. 1, vibration isolation layer 60 may include an energy dissipation mechanism 80. Energy dissipation mechanism 80 may be configured to dissipate and/or dampen energy, such as mechanical energy, within the vibration isolation layer and/or between platform 64 and mounting region 12. Such a configuration further may decrease motion, harmonic motion, and/or relatively lower-frequency motion, between the platform and the mounting region. As an example, the presence of energy dissipation mechanism 80 may decrease relative motion between the probe station and/or the platform and the mounting region in the Hertz to 10's of Hertz range. Examples of energy dissipation mechanism 80 include one or more flexible sliding plates, a liquid damper, a gas damper, and/or a shock absorber.

As illustrated in dashed lines in FIG. 1, vibration isolation layer 60 may include and/or define a base 68. Base 68 may be shaped, sized, and/or constructed to decrease and/or lower a center of gravity, or an overall center of gravity, of probe station 30 and/or of measurement system 20. Such a configuration further may decrease the potential for motion, relative motion, and/or harmonic motion between the probe station and/or the platform and the mounting region.

This may be accomplished in any suitable manner. As an example, platform 64 may define a recess 65 that may extend into the platform and/or that may define at least a region of upper surface 66. As an example, recess 65 may extend into the platform a threshold percentage of platform thickness 67. Examples of the threshold percentage of platform thickness 67 include at least 10%, at least 20%, at least 30%, at least 40%, at least 50%, at least 60%, at least 70%, at most 90%, at most 80%, at most 70%, at most 60%, at most 50%, and/or at most 40%.

In such a configuration, probe station 30 and/or loader 96 may be at least partially received into recess 65. As another example, the plurality of vibration isolation mechanisms 70 may be positioned outside a footprint of supported assembly 26, of probe station 30, and/or of loader 96. Stated differently, vibration isolation mechanisms 70 may be positioned outside a vertical projection of the supported assembly, of the probe station, and/or of the loader onto the mounting region. Such a configuration may permit and/or facilitate utilization of relatively taller vibration isolation mechanisms 70 without the need for a proportionate increase in the height of the probe station and/or of the loader. Additionally or alternatively, such a configuration may increase a stability of platform 64 and/or may decrease a natural frequency for motion of the platform.

As another example, supported assembly 26, or a combination of supported assembly 26 and platform 64, may define a center of gravity 28, and a spacing among the plurality of vibration isolation mechanisms 70 may be at least a threshold multiple of a height 29 of the center of gravity. Examples of the threshold multiple include at least 1.5, at least 1.6, at least 1.7, at least 1.8, at least 1.9, at least 2, at least 2.2, at least 2.4, at least 2.6, at least 2.8, at least 3, at most 4, at most 3.8, at most 3.6, at most 3.4, at most 3.2, at most 3, at most 2.8, at most 2.6, at most 2.4, at most 2.2, and/or at most 2. Examples of the spacing include a distance between the plurality of vibration isolation mechanisms as measured within a plane that is parallel to upper surface 66 of platform 64, an average distance between the plurality of vibration isolation mechanisms as measured within the plane, and/or a minimum distance between two closest vibration isolation mechanisms as measured within the plane.

In conventional probe stations, vibration isolation may be provided via a relatively larger, more complex, and/or heavier conventional vibration isolation structure. Such conventional vibration isolation structures generally are constructed on a ground floor of a building and include an excavated hole that generally is on the order of a meter deep. The hole is filled with rubber and capped with a thick granite block, which also is on the order of a meter thick. While effective in certain circumstances, such conventional vibration isolation structures are costly and time-consuming to construct. In addition, their installation generally is limited to ground floors, and their overall size and scope often makes retrofitting such conventional vibration isolation structures into an existing facility prohibitively expensive.

In contrast, vibration isolation layers 60, according to the present disclosure, economically may be positioned and/or utilized within the existing facility and/or on an existing mounting region. With this in mind, mounting regions 12, according to the present disclosure, may be flat and/or planar mounting regions and/or may be on a floor other than the ground floor of the facility. Additionally or alternatively, mounting regions 12 may be free of, or may not include, a below-grade recess, or hole, that is vertically below a remainder of the floor surface, that is vertically below the vibration isolation layer, and/or that at least partially contains and/or houses the vibration isolation layer.

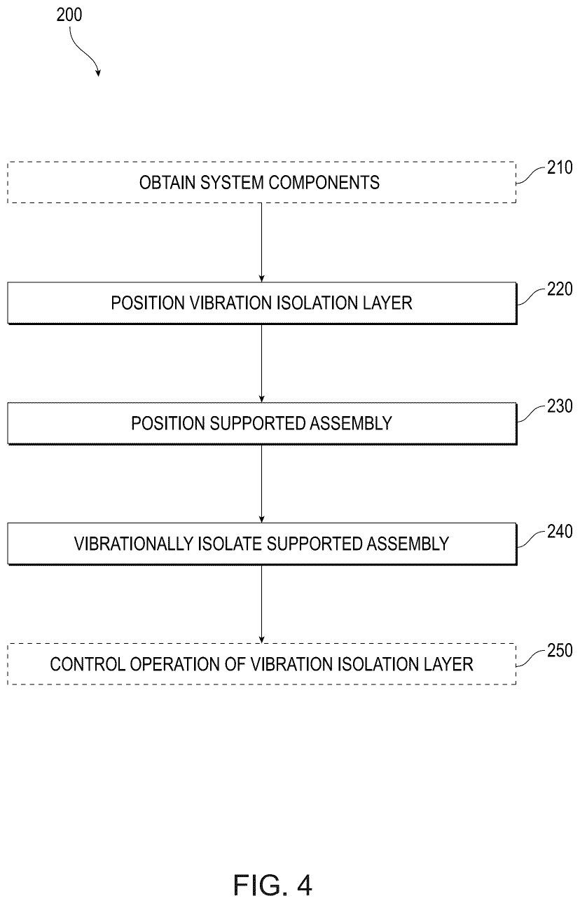

FIG. 4 is a flowchart depicting examples of methods 200 of installing a measurement system, according to the present disclosure, that is configured to test a device under test (DUT) formed on a substrate. Examples of the measurement system and/or components thereof are disclosed herein with reference to measurement systems 20. Methods 200 may include obtaining system components at 210, and methods 200 include positioning a vibration isolation layer at 220 and positioning a supported assembly at 230. Methods 200 also include vibrationally isolating the supported assembly at 240 and may include controlling operation of the vibration isolation layer at 250.

Obtaining the system components at 210 may include obtaining one or more system components of the measurement system in any suitable manner. As an example, and as discussed in more detail herein, the supported assembly may include an optical measurement layer, which may be configured for optical communication and/or for non-contact optical communication with the DUT. In such examples, the obtaining at 210 may include obtaining the optical measurement layer and the vibration isolation layer from the same manufacturer and/or from the same vendor. Additionally or alternatively, the obtaining at 210 may include obtaining the optical measurement layer and the vibration isolation layer from a first manufacturer and/or from a first vendor. In some such examples, the obtaining at 210 also may include obtaining one or more other components of the supported assembly, such as a probe station and/or an electrical measurement layer, from a second manufacturer that differs from the first manufacturer and/or from a second vendor that differs from the first vendor.

Examples of the supported assembly are disclosed herein with reference to supported assembly 26. Examples of the optical measurement layer are disclosed herein with reference to optical measurement layer 50. Examples of the DUT are disclosed herein with reference to DUT 104. Examples of the vibration isolation layer are disclosed herein with reference to vibration isolation layer 60. Examples of the probe station are disclosed herein with reference to probe station 30. Examples of the electrical measurement layer are disclosed herein with reference to electrical measurement layer 42.

Positioning the vibration isolation layer at 220 may include positioning the vibration isolation layer within a mounting region. The vibration isolation layer includes a platform and is configured to vibrationally isolate the platform from the mounting region. Examples of the mounting region are disclosed herein with reference to mounting region 12. Examples of the platform are disclosed herein with reference to platform 64.

The positioning at 220 may be performed in any suitable manner. As an example, the positioning at 220 may include positioning the vibration isolation layer on an existing mounting region, such as to retrofit the existing mounting region to be utilized with the measurement system. In some such examples, the existing mounting region may be planar, or at least substantially planar. In some examples, the existing mounting region may be free of and/or may not include a below-grade recess that extends vertically below a floor surface that surrounds the existing mounting region. Stated differently, and as discussed in more detail herein, methods 200 may include installing the measurement system without excavating and/or otherwise forming a hole, without filling the hole with a resilient material, such as rubber, and/or without positioning a granite block within the hole. Stated still differently, the positioning at 220 may include positioning the vibration isolation layer on, directly on, above, and/or entirely above the floor surface, or a grade of the floor surface.

Positioning the supported assembly at 230 may include positioning the supported assembly on an upper surface of the platform. Examples of the upper surface are disclosed herein with reference to upper surface 66. It is within the scope of the present disclosure that the positioning at 230 may include positioning any suitable component and/or subset of the supported assembly, individually or as a unit, on the platform.

Vibrationally isolating the supported assembly at 240 may include vibrationally isolating the supported assembly from the mounting region via the vibration isolation layer. This may include absorbing vibration, which propagates through the mounting region, utilizing a vibration isolation mechanism, or a plurality of vibration isolation mechanisms, of the vibration isolation layer. Additionally or alternatively, the vibrationally isolating at 240 may include absorbing and/or dissipating vibrational energy, such as via an energy dissipation mechanism of the vibration isolation layer. Examples of the vibration isolation mechanism and of the energy dissipation mechanism are disclosed herein with reference to vibration isolation mechanism 70 and energy dissipation mechanism 80, respectively.

Controlling operation of the vibration isolation layer at 250 may include controlling operation of the vibration isolation layer in any suitable manner. As an example, and as discussed, the supported assembly may include the optical measurement layer. In some such examples, the optical measurement layer may include an optical measurement layer controller, which may be programmed to control the operation of one or more components of the optical measurement layer. In some such examples, the optical measurement layer controller also may be programmed to control the operation of the vibration isolation layer. As an example, and as discussed in more detail herein, the vibration isolation layer may include one or more actively controlled vibration isolators, and the controlling at 250 may include controlling operation of the one or more actively controlled vibration isolators utilizing the optical measurement layer controller. Such a configuration may permit and/or facilitate vibrational isolation, between the optical measurement layer and the mounting region, that is based upon the optical measurement layer and/or that is sufficient for consistent and/or reliable operation of the optical measurement layer.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entities in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” may mean A alone, B alone, C alone, A and B together, A and C together, B and C together, A, B, and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

As used herein, “at least substantially,” when modifying a degree or relationship, may include not only the recited “substantial” degree or relationship, but also the full extent of the recited degree or relationship. A substantial amount of a recited degree or relationship may include at least 75% of the recited degree or relationship. For example, an object that is at least substantially formed from a material includes objects for which at least 75% of the objects are formed from the material and also includes objects that are completely formed from the material. As another example, a first length that is at least substantially as long as a second length includes first lengths that are within 75% of the second length and also includes first lengths that are as long as the second length.

Illustrative, non-exclusive examples of vibration isolation layers, measurement systems, and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A vibration isolation layer for a measurement system, the vibration isolation layer comprising:
a platform that defines an upper surface configured to support a supported assembly that includes at least one, and optionally both, of a probe station of the measurement system and a loader of the measurement system; and
a vibration isolation mechanism, or a plurality of vibration isolation mechanisms, positioned to support the platform relative to a mounting region that supports the vibration isolation layer, wherein the vibration isolation mechanism is configured to permit relative motion between the platform and the mounting region to vibrationally isolate the platform from the mounting region.

A2. The vibration isolation layer of paragraph A1, wherein the platform defines a recess sized to receive at least a region of at least one of the probe station and the loader.

A2.1. The vibration isolation layer of paragraph A2, wherein the recess extends into the platform a threshold percentage of a platform thickness of the platform, optionally wherein the threshold percentage is at least one of:
(i) at least 10%, at least 20%, at least 30%, at least 40%, at least 50%, at least 60%, or at least 70%; and
(ii) at most 90%, at most 80%, at most 70%, at most 60%, at most 50%, or at most 40%.

A3. The vibration isolation layer of any of paragraphs A1-A2.1, wherein the platform defines a platform thickness, or an average platform thickness, of at least one of:
(i) at least 100 millimeters (mm), at least 120 mm, at least 140 mm, at least 160 mm, at least 180 mm, or at least 200 mm, and
(ii) at most 400 mm, at most 350 mm, at most 300 mm, at most 250 mm, at most 200 mm, or at most 150 mm.

A4. The vibration isolation layer of any of paragraphs A1-A3, wherein the platform is at least partially, or even completely, formed from a platform material, optionally wherein the platform material includes at least one of a metal, a steel, a stainless steel, lead, a stone, a mineral glass, and granite.

A5. The vibration isolation layer of paragraph A4, wherein the platform material defines a platform material density of at least one of:
(i) at least 2 grams per cubic centimeter (g/cc), at least 2.5 g/cc, at least 3 g/cc, at least 4 g/cc, at least 5 g/cc, at least 6 g/cc, at least 7 g/cc, at least 8 g/cc, at least 9 g/cc, at least 10 g/cc, at least 11 g/cc, or at least 12 g/cc; and
(ii) at most 16 g/cc, at most 14 g/cc, at most 12 g/cc, at most 10 g/cc, at most 8 g/cc, at most 6 g/cc, or at most 4 g/cc.

A6. The vibration isolation layer of any of paragraphs A4-A5, wherein the platform material is at least one of a non-ringing material, a self-damping material, and a vibration-damping material.

A7. The vibration isolation layer of any of paragraphs A1-A6, wherein the vibration isolation mechanism includes at least one of a passive vibration isolator, a passive air vibration isolator, a passive air vibration isolation spring, and a passive elastomeric gas-containing volume configured to be inflated to vibrationally isolate the platform from the mounting region.

A8. The vibration isolation layer of any of paragraphs A1-A7, wherein the vibration isolation mechanism includes at least one of an actively controlled vibration isolator, an actively controlled air vibration isolator, and an actively controlled elastomeric gas-containing volume configured to be selectively inflated to vibrationally isolate the platform from the mounting region.

A9. The vibration isolation layer of paragraph A8, wherein the vibration isolation layer further includes a gas pressure regulation structure configured to regulate an internal gas pressure within the vibration isolation mechanism.

A10. The vibration isolation layer of any of paragraphs A1-A9, wherein the vibration isolation layer includes the plurality of vibration isolation mechanisms, and further wherein each vibration isolation mechanism of the plurality of vibration isolation mechanisms is at least one of:
(i) positioned outside a footprint of the supported assembly; and
(ii) positioned outside a vertical projection of the supported assembly onto the mounting region.

A11. The vibration isolation layer of any of paragraphs A1-A10, wherein the vibration isolation layer includes the plurality of vibration isolation mechanisms, wherein the plurality of vibration isolation mechanisms defines a spacing, wherein the supported assembly defines a center of gravity, and further wherein the spacing is at least a threshold spacing multiple of a height of the center of gravity.

A12. The vibration isolation layer of paragraph A11, wherein the threshold spacing multiple is at least one of:
(i) at least 1.5, at least 1.6, at least 1.7, at least 1.8, at least 1.9, at least 2, at least 2.2, at least 2.4, at least 2.6, at least 2.8, or at least 3; and
(ii) at most 4, at most 3.8, at most 3.6, at most 3.4, at most 3.2, at most 3, at most 2.8, at most 2.6, at most 2.4, at most 2.2, or at most 2.

A13. The vibration isolation layer of any of paragraphs A11-A12, wherein the spacing includes at least one of:
(i) a distance between the plurality of vibration isolation mechanisms as measured within a plane that is parallel to the upper surface of the platform; and
(ii) an average distance between the plurality of vibration isolation mechanisms as measured within the plane that is parallel to the upper surface of the platform.

A14. The vibration isolation layer of any of paragraphs A11-A13, wherein the supported assembly further includes at least one of the platform, a measurement layer, and a translation assembly.

A15. The vibration isolation layer of any of paragraphs A1-A14, wherein the vibration isolation layer further includes an energy dissipation mechanism configured to at least one of:
(i) dissipate mechanical energy between the platform and the mounting region; and
(ii) dampen mechanical motion between the platform and the mounting region.

A16. The vibration isolation layer of paragraph A15, wherein the energy dissipation mechanism includes at least one of a flexible sliding plate, a plurality of flexible sliding plates, a liquid damper, a gas damper, and a shock absorber.

A17. The vibration isolation layer of any of paragraphs A1-A16, wherein the vibration isolation layer further includes a base that supports the vibration isolation mechanism relative to the mounting region.

A18. The vibration isolation layer of paragraph A17, wherein the vibration isolation layer includes the plurality of vibration isolation mechanisms, and further wherein the base supports the plurality of vibration isolation mechanisms outside a/the footprint of the probe station.

B1. A measurement system, comprising:
the vibration isolation layer of any of paragraphs A1-A18; and
a/the supported assembly that is supported by the vibration isolation mechanism via the platform, wherein the supported assembly includes at least one of:
(i) a probe station that includes a support surface configured to support a substrate;
(ii) a measurement layer configured to test a device under test (DUT) formed on the substrate;
(iii) a loader configured to receive a cassette that includes a plurality of substrates, wherein each substrate of the plurality of substrates includes a corresponding plurality of DUTs; and
(iv) a translation assembly configured to move the support surface and the measurement layer relative to one another to facilitate alignment between the measurement layer and the DUT.

B2. The measurement system of paragraph B1, wherein the probe station includes a chuck that defines the support surface.

B3. The measurement system of paragraph B2, wherein the chuck includes at least one of a thermal chuck, a temperature-controlled chuck, a vacuum chuck, and an electrically shielded chuck.

B4. The measurement system of any of paragraphs B1-B3, wherein the translation assembly is configured to at least one of:
(i) move the support surface relative to the measurement layer; and
(ii) move the measurement layer relative to the support surface.

B5. The measurement system of any of paragraphs B1-B4, wherein the translation assembly includes at least one of a linear actuator and a rotary actuator.

B6. The measurement system of any of paragraphs B1-B5, wherein the measurement layer includes an electrical measurement layer configured to electrically test the DUT.

B7. The measurement system of paragraph B5, wherein the electrical measurement layer includes a plurality of electrical probes configured to electrically contact, or to physically and electrically contact, corresponding contact pads of the DUT to electrically test the DUT.

B8. The measurement system of paragraph B7, wherein the probe station further includes an electrical signal generation and analysis assembly configured to at least one of provide an electrical test signal to the DUT via the plurality of electrical probes and receive an electrical resultant signal from the DUT via the plurality of electrical probes.

B9. The measurement system of any of paragraphs B6-B8, wherein the electrical measurement layer forms a portion of the probe station.

B10. The measurement system of any of paragraphs B1-B9, wherein the probe station includes an optical measurement layer configured to optically test the DUT.

B11. The measurement system of paragraph B10, wherein the optical measurement layer includes a plurality of optical probes configured for optical communication, or non-contact optical communication, with the DUT.

B12. The measurement system of paragraph B11, wherein the optical measurement layer includes an optical signal generation and analysis assembly configured to at least one of provide an optical test signal to the DUT via the plurality of optical probes and receive an optical resultant signal from the DUT via the plurality of optical probes.

B13. The measurement system of any of paragraphs B11-B12, wherein the optical measurement layer includes an optical microscope configured to collect an optical image of at least one of the plurality of optical probes and at least a region of the DUT, optionally wherein the optical microscope is configured to facilitate optical alignment between the plurality of optical probes and the DUT.

B14. The measurement system of any of paragraphs B11-B13, wherein the vibration isolation layer is configured to vibrationally isolate the platform from the mounting region to provide an amount of vibration isolation that is based, at least in part, on a target maximum magnitude of vibrational motion between the plurality of optical probes and the DUT.

B15. The measurement system of any of paragraphs B10-B14, wherein the optical measurement layer is a modular optical measurement layer that is operatively attached to a remainder of the probe station.

B16. The measurement system of any of paragraphs B10-B15, wherein the optical measurement layer further includes an optical measurement layer controller programmed to control the operation of the optical measurement layer.

B17. The measurement system of paragraph B16, wherein the optical measurement layer controller also is programmed to control the operation of the vibration isolation layer.

B18. The measurement system of paragraph B17, wherein the optical measurement layer controller is programmed to regulate a height of the platform via control of the vibration isolation mechanism, optionally wherein the optical measurement layer controller is programmed to at least one of:
(i) lower the platform at least one of to a lower height limit and against a lower height stop when the cassette is being positioned on the loader;
(ii) lower the platform to the at least one of the lower height limit and against the lower height stop when the cassette is being removed from the loader; and
(iii) raise the platform to a vibration isolation height at which the platform effectively isolates the supported assembly from vibration prior to testing of the DUT.

B19. The measurement system of any of paragraphs B1-B18, wherein the loader is configured to move a selected substrate of the plurality of substrates between the cassette and the probe station to facilitate testing of one or more DUTS formed on the selected substrate by the probe station, optionally wherein the loader is configured to at least one of:
(i) remove the selected substrate from the cassette and to position the selected substrate on a/the support surface of the probe station; and
(ii) remove the selected substrate from the support surface of the probe station and position the selected substrate within the cassette.

B20. The measurement system of any of paragraphs B1-B19, wherein the measurement system includes the mounting region, and further wherein the mounting region at least one of:
(i) is a planar, or at least substantially planar, mounting region; and
(ii) is free of, or does not include, a below-grade recess that is vertically below a remainder of a floor surface that surrounds the mounting region.

B21. The measurement system of any of paragraphs B1-B20, wherein the vibration isolation layer and an/the optical measurement layer of the measurement system are provided by a first vendor, or by the same vendor.

B22. The measurement system of paragraph B21, wherein at least one remaining component of the probe station is provided by a second vendor, or by another vendor, that differs from the first vendor.

C1. A method of installing a measurement system configured to test a device under test (DUT) that is formed on a substrate, the method comprising:
positioning, within a mounting region, a vibration isolation layer, wherein the vibration isolation layer includes a platform, and further wherein the vibration isolation layer is configured to vibrationally isolate the platform from the mounting region;
positioning, on an upper surface of the platform, a supported assembly; and
vibrationally isolating the supported assembly from the mounting region via the vibration isolation layer.

C2. The method of paragraph C1, wherein the supported assembly includes a probe station, and further wherein the positioning the supported assembly includes positioning the probe station on the upper surface.

C3. The method of paragraph C2, wherein the supported assembly includes an optical measurement layer configured for optical communication, or non-contact optical communication, with the DUT, wherein the optical measurement layer includes an optical measurement layer controller, and further wherein the method includes controlling the operation of the vibration isolation layer utilizing the optical measurement layer controller.

C4. The method of paragraph C3, wherein the method further includes obtaining the vibration isolation layer and the optical measurement layer from a first manufacturer and obtaining the probe station from a second manufacturer that differs from the first manufacturer.

C5. The method of any of paragraphs C1-C3, wherein the positioning the vibration isolation layer includes positioning on an existing mounting region, optionally wherein the existing mounting region at least one of:
(i) is a planar, or at least substantially planar, existing mounting region; and
(ii) is free of, or does not include, a below-grade recess that is vertically below a remainder of a floor surface that surrounds the existing mounting region.

C6. The method of any of paragraphs C1-C5, wherein the measurement system includes any suitable structure, function, and/or feature of any of the measurement systems of any of paragraphs B1-B22.

### INDUSTRIAL APPLICABILITY

The vibration isolation layers, measurement systems, and methods disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A vibration isolation layer for a measurement system, the vibration isolation layer comprising:
a platform that defines an upper surface configured to support a supported assembly that includes at least one of a probe station of the measurement system and a loader of the measurement system, wherein the platform defines a recess sized to receive at least a region of at least one of the probe station and the loader, wherein the recess extends into the platform a threshold percentage of a platform thickness of the platform, and further wherein the threshold percentage is at least 10%; and
a plurality of vibration isolation mechanisms positioned to support the platform relative to a mounting region that supports the vibration isolation layer, wherein the plurality of vibration isolation mechanisms is configured to permit relative motion between the platform and the mounting region to vibrationally isolate the platform from the mounting region.

2. The vibration isolation layer of claim 1, wherein each vibration isolation mechanism of the plurality of vibration isolation mechanisms is at least one of:
(i) positioned outside a footprint of the supported assembly; and
(ii) positioned outside a vertical projection of the supported assembly onto the mounting region.

3. The vibration isolation layer of claim 1, wherein the platform defines a platform thickness of at least 100 millimeters (mm) and at most 400 mm.

4. The vibration isolation layer of claim 1, wherein each vibration isolation mechanism of the plurality of vibration isolation mechanisms includes at least one of a passive vibration isolator, a passive air vibration isolator, a passive air vibration isolation spring, and a passive elastomeric gas-containing volume configured to be inflated to vibrationally isolate the platform from the mounting region.

5. The vibration isolation layer of claim 1, wherein each vibration isolation mechanism of the plurality of vibration isolation mechanisms includes at least one of an actively controlled vibration isolator, an actively controlled air vibration isolator, and an actively controlled elastomeric gas-containing volume configured to be selectively inflated to vibrationally isolate the platform from the mounting region.

6. The vibration isolation layer of claim 5, wherein the vibration isolation layer further includes a gas pressure regulation structure configured to regulate an internal gas pressure within the vibration isolation mechanism.

7. The vibration isolation layer of claim 1, wherein the plurality of vibration isolation mechanisms defines a spacing, wherein the supported assembly defines a center of gravity, wherein the spacing is at least a threshold spacing multiple of a height of the center of gravity, and further wherein the threshold spacing multiple is at least 1.5.

8. The vibration isolation layer of claim 1, wherein the vibration isolation layer further includes an energy dissipation mechanism configured to at least one of:
(i) dissipate mechanical energy between the platform and the mounting region; and
(ii) dampen mechanical motion between the platform and the mounting region.

9. The vibration isolation layer of claim 8, wherein the energy dissipation mechanism includes at least one of a flexible sliding plate, a plurality of flexible sliding plates, a liquid damper, a gas damper, and a shock absorber.

10. A measurement system, comprising:
the vibration isolation layer of claim 1; and
the supported assembly that is supported by the vibration isolation mechanism via the platform, wherein the supported assembly includes at least one of:
(i) a probe station that includes a support surface configured to support a substrate;
(ii) a measurement layer configured to test a device under test (DUT) formed on the substrate;
(iii) a loader configured to receive a cassette that includes a plurality of substrates, wherein each substrate of the plurality of substrates includes a corresponding plurality of DUTs; and
(iv) a translation assembly configured to move the support surface and the measurement layer relative to one another to facilitate alignment between the measurement layer and the DUT.

11. A measurement system, comprising:
a vibration isolation layer that includes:
(i) a platform that defines an upper surface; and
(ii) a plurality of vibration isolation mechanisms positioned to support the platform relative to a mounting region that supports the vibration isolation layer, wherein the plurality of vibration isolation mechanisms is configured to permit relative motion between the platform and the mounting region to vibrationally isolate the platform from the mounting region; and
a supported assembly supported by the upper surface of the platform, wherein the supported assembly includes a measurement layer configured to test a device under test (DUT) formed on a substrate, wherein the supported assembly includes an optical measurement layer configured to optically test the DUT, wherein the optical measurement layer further includes an optical measurement layer controller programmed to control the operation of the optical measurement layer, and further wherein the optical measurement layer controller also is programmed to control the operation of the vibration isolation layer.

12. The measurement system of claim 11, wherein the optical measurement layer controller is programmed to regulate a height of the platform via control of the vibration isolation mechanism.

13. The measurement system of claim 12, wherein the supported assembly includes a loader configured to receive a cassette that includes a plurality of substrates, and further wherein the optical measurement layer controller is programmed to at least one of:
(i) lower the platform at least one of to a lower height limit and against a lower height stop when the cassette is being positioned on the loader;
(ii) lower the platform to the at least one of the lower height limit and against the lower height stop when the cassette is being removed from the loader; and
(iii) raise the platform to a vibration isolation height at which the platform effectively isolates the supported assembly from vibration prior to testing of the DUT.

14. The measurement system of claim 11, wherein the optical measurement layer includes a plurality of optical probes configured for optical communication with the DUT, and further wherein the optical measurement layer includes an optical signal generation and analysis assembly configured to at least one of provide an optical test signal to the DUT via the plurality of optical probes and receive an optical resultant signal from the DUT via the plurality of optical probes.

15. The measurement system of claim 14, wherein the optical measurement layer includes an optical microscope configured to collect an optical image of at least one of the plurality of optical probes and at least a region of the DUT to facilitate optical alignment between the plurality of optical probes and the DUT.

16. The measurement system of claim 14, wherein the vibration isolation layer is configured to vibrationally isolate the platform from the mounting region to provide an amount of vibration isolation that is based, at least in part, on a target maximum magnitude of vibrational motion between the plurality of optical probes and the DUT.

17. The measurement system of claim 11, wherein the optical measurement layer is a modular optical measurement layer that is operatively attached to a remainder of the probe station.

18. The measurement system of claim 11, wherein the measurement layer includes an electrical measurement layer configured to electrically test the DUT, and further wherein the electrical measurement layer includes a plurality of electrical probes configured to electrically contact corresponding contact pads of the DUT to electrically test the DUT.

19. The measurement system of claim 11, wherein the measurement system includes the mounting region, and further wherein the mounting region at least one of:
(i) is a planar mounting region; and
(ii) is free of a below-grade recess that is vertically below a remainder of a floor surface that surrounds the mounting region.

20. A method of installing a measurement system configured to test a device under test (DUT) that is formed on a substrate, the method comprising:
positioning, within a mounting region, a vibration isolation layer, wherein the vibration isolation layer includes a platform, and further wherein the vibration isolation layer is configured to vibrationally isolate the platform from the mounting region;
positioning, on an upper surface of the platform, a supported assembly, wherein the supported assembly includes a probe station and an optical measurement layer configured for optical communication with the DUT, wherein the optical measurement layer includes an optical measurement layer controller, and further wherein the positioning the supported assembly includes positioning the probe station and the optical measurement layer on the upper surface;
vibrationally isolating the supported assembly from the mounting region via the vibration isolation layer; and
controlling the operation of the vibration isolation layer utilizing the optical measurement layer controller.
